(19) United States
(12) Patent Application Publication
(10) Pub. No.: US 2025/0338694 A1
(43) Pub. Date: Oct. 30, 2025

(54) LIGHT-EMITTING DEVICE

(71) Applicant: Bridgelux Optoelectronics (Xiamen) Co., Ltd., Xiamen (CN)

(72) Inventors: JINGQIONG ZHANG, Xiamen (CN); HUIJIAO YANG, Xiamen (CN); JING CHEN, Xiamen (CN); GUOHENG QIN, Xiamen (CN); CHEN CHU, Xiamen (CN); DEBING HUANG, Xiamen (CN); CONGLIN WU, Xiamen (CN)

(21) Appl. No.: 18/991,414

(22) Filed: Dec. 21, 2024

(30) Foreign Application Priority Data
Apr. 29, 2024 (CN) 2024105339612

(51) Int. Cl. H10H 29/854; H01L 25/075; H10H 20/85

(52) U.S. Cl. CPC H10H 29/854; H01L 25/0753; H10H 20/8502

(57) ABSTRACT

A light-emitting device includes: a first light-emitting unit with a chromaticity coordinate x ranging from 0.53 to 0.6, and a chromaticity point located proximate to a blackbody radiation curve; a second light-emitting unit with a chromaticity coordinate x ranging from 0.4 to 0.48, and a chromaticity point located above the blackbody radiation curve; and a third light-emitting unit with a chromaticity coordinate x ranging from 0.18 to 0.24, and a chromaticity point located above the blackbody radiation curve. An area surrounded by the chromaticity points of the first light-emitting unit, the second light-emitting unit and the third light-emitting unit covers an area on the blackbody radiation curve with a CCT range of 1800 K to 10000 K, which can achieve a wide-range CCT tuning, and make CIExy coordinates fit the blackbody radiation curve to tune a product during the tuning process.

### CROSS-REFERENCE TO RELATED APPLICATION

This application claims priority to Chinese Patent Application No. 202410533961.2, filed on Apr. 29, 2024, which is herein incorporated by reference in its entirety.

### TECHNICAL FIELD

The disclosure relates to the field of lighting technologies, and more particularly to a light-emitting device.

### BACKGROUND

Human life is inseparable from lighting, and a most basic element of lighting is a light source. Especially with the development of lighting technology, common lighting sources have evolved from early incandescent lamps and fluorescent lamps to the more widely used light-emitting diode (LED) lights in recent years. Based on the development of LED lighting technology, the need for wide-range CCT (correlated color temperature) tuning has become an important direction. Referring to FIG. 1, a solution for wide-range CCT tuning is using LED white lights with three different CCTs, since the blackbody radiation curve (BBC) is arc-shaped, even the CIExy of the three LED lights all fall on BBC, the CCT tuning trajectory will deviate from the blackbody radiation curve, thus there is a deviation between color of a chromaticity coordinate by tuning and color of a standard chromaticity point.

Therefore, there is an urgent need for a light-emitting device that can achieve a wide-range of CCT tuning and CIExy coordinates fitting the BBC during the tuning process.

### SUMMARY

In order to overcome at least a part of defeats and disadvantages of the related art, an embodiment of the disclosure provides a light-emitting device.

Specifically, the light-emitting device provided by the embodiment of the disclosure includes: a first light-emitting unit, a second light-emitting unit and a third light-emitting unit. A chromaticity coordinate x of the first light-emitting unit is in a range of 0.53 to 0.6, and a chromaticity point of the first light-emitting unit is located proximate to a blackbody radiation curve. A chromaticity coordinate x of the second light-emitting unit is in a range of 0.4 to 0.48, and a chromaticity point of the second light-emitting unit is located above the blackbody radiation curve. A chromaticity coordinate x of the third light-emitting unit is in a range of 0.18 to 0.24, and a chromaticity point of the third light-emitting unit is located above the blackbody radiation curve. An area surrounded by the chromaticity point of the first light-emitting unit, the chromaticity point of the second light-emitting unit and the chromaticity point of the third light-emitting unit covers an area on the blackbody radiation curve with a CCT range of 1800 K to 10000 K.

It can be seen from the above that the embodiment of the disclosure selects at least three specific light-emitting units, so that the light-emitting device of the embodiment can achieve a wide-range CCT tuning (e.g., 1800 K-10000 K), and make the CCT tuning trajectory fit the blackbody radiation curve to tune the product during the tuning process.

### BRIEF DESCRIPTION OF DRAWINGS

In order to describe technical solutions of embodiments of the disclosure clearly, the drawings required for the description of the embodiments are briefly introduced below. Apparently, the drawings in the below descriptions are merely some of the embodiments of the disclosure. For those skilled in the art, other drawings can be obtained according to the drawings without creative work.

FIG. 1 illustrates a schematic comparison diagram of a blackbody radiation curve and a CCT tuning trajectory in the related art.

FIG. 2 illustrates a schematic structural diagram of a light-emitting device according to an embodiment of the disclosure.

FIG. 3 illustrates a schematic diagram of chromaticity coordinates of the light-emitting device of FIG. 2.

FIG. 4 illustrates a spectral schematic diagram of the light-emitting device of FIG. 2.

FIG. 5 illustrates a spectral schematic diagram of the light-emitting device of FIG. 2.

FIG. 6 illustrates a schematic structural diagram of a bracket of the light-emitting device according to an embodiment of the disclosure.

FIG. 7 illustrates a schematic structural diagram of a light-emitting device according to an embodiment of the disclosure.

FIG. 8 illustrates a schematic structural diagram of a light-emitting device according to an embodiment of the disclosure.

FIG. 9 illustrates a schematic structural diagram of a light-emitting device according to an embodiment of the disclosure.

FIG. 10 illustrates a schematic structural diagram of a light-emitting device according to an embodiment of the disclosure.

### DETAILED DESCRIPTION OF EMBODIMENTS

In order to make purposes, technical solutions and advantages of embodiments of the disclosure clearer, the technical solutions in the embodiments of the disclosure will be clearly and completely described below in conjunction with drawings. Apparently, the described embodiments are merely some of the embodiments of the disclosure, not all embodiments. Based on the embodiments described in the disclosure, all other embodiments obtained by those skilled in the art without creative work belong to a scope of protection of the disclosure.

In the embodiments of the disclosure, descriptions of “first”, “second” and the like are only for descriptive purposes and cannot be understood as indicating or implying their relative importance or implicitly indicating the number of the indicated technical features. Therefore, the features defined as “first” or “second” may explicitly or implicitly include at least one of the features.

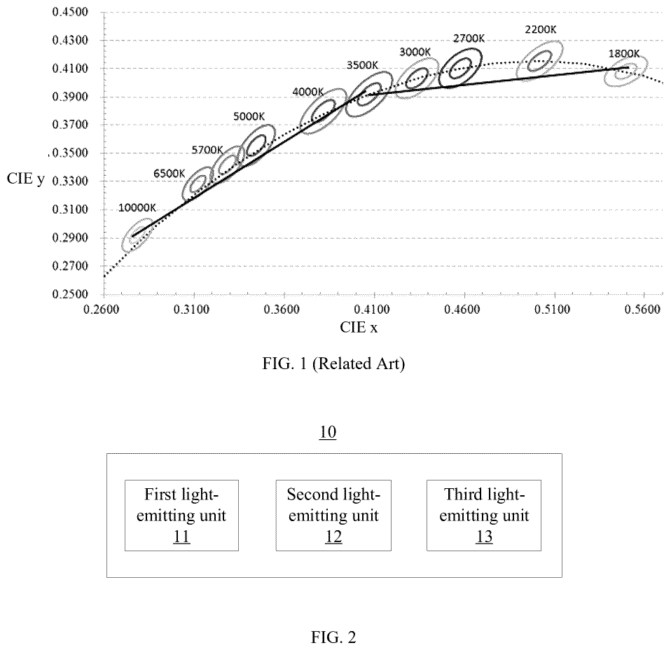

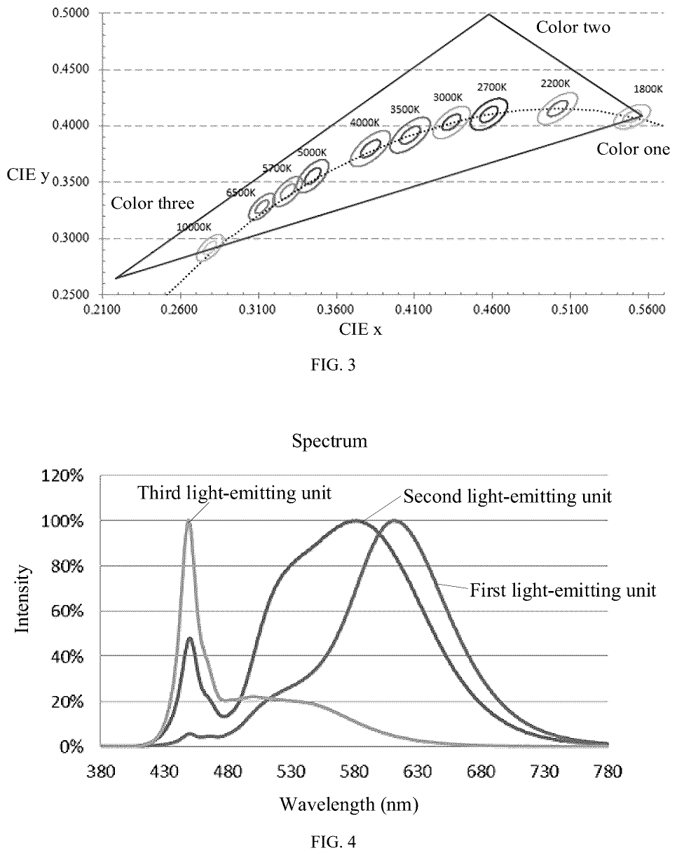

As shown in FIG. 2 and FIG. 3, embodiments of the disclosure provide a light-emitting device 10, including: a first light-emitting unit 11, a second light-emitting unit 12 and a third light-emitting unit 13. In FIG. 3, color one represents light emitted from the first light-emitting unit 11 after it is illuminated, color two represents light emitted from the second light-emitting unit 12 after it is illuminated, and color three represents light emitted from the third light-emitting unit 13 after it is illuminated. Specifically, a chromaticity coordinate x of the first light-emitting unit 11 is in a range of 0.53 to 0.6, and a chromaticity point of the first light-emitting unit 11 is located proximate to a blackbody radiation curve. A chromaticity coordinate x of the second light-emitting unit 12 is in a range of 0.4 to 0.48, and a chromaticity point of the second light-emitting unit 12 is located above the blackbody radiation curve. A chromaticity coordinate x of the third light-emitting unit 13 is in a range of 0.18 to 0.24, and a chromaticity point of the third light-emitting unit 13 is located above the blackbody radiation curve. An area surrounded by the chromaticity points of the first light-emitting unit 11, the second light-emitting unit 12 and the third light-emitting unit 13 covers an area on the blackbody radiation curve with a CCT range of 1800 K to 10000 K. As shown in FIG. 3, the light-emitting device 10 provided by the embodiment can achieve a wide-range CCT tuning (e.g., 1800 K-10000 K), and CIExy coordinates of the light emitted by the light-emitting device 10 under the target CCT can fit the blackbody radiation curve to tune the product during the tuning process, and a color tolerance can meet the requirements of 4-step.

In an embodiment, a distance between the chromaticity point of the first light-emitting unit 11 and the chromaticity point of the second light-emitting unit 12 is in a range of 0.12 to 0.16, a distance between the chromaticity point of the second light-emitting unit 12 and the chromaticity point of the third light-emitting unit 13 is in a range of 0.27 to 0.34, and a distance between the chromaticity point of the third light-emitting unit 13 and the chromaticity point of the first light-emitting unit 11 is in a range of 0.32 to 0.38. An area of a color gamut area (i.e., the area surrounded by the chromaticity points of the first light-emitting unit 11, the second light-emitting unit 12 and the third light-emitting unit 13) surrounded by the first light-emitting unit 11, the second light-emitting unit 12 and the third light-emitting unit 13 is further limited through limiting the distances among the chromaticity point of first light-emitting unit 11, the chromaticity point of the second light-emitting unit 12 and the chromaticity point of the third light-emitting unit 13. Through this setting, within a same CCT range covered by the light-emitting device 10, the area of the color gamut area surrounded by the three light-emitting units is small, and the luminous efficiency of the light-emitting device 10 can be high.

In another embodiment, a chromaticity coordinate y of the first light-emitting unit 11 is in a range of 0.4 to 0.43, a chromaticity coordinate y of the second light-emitting unit 12 is in a range of 0.45 to 0.56, and a chromaticity coordinate y of the third light-emitting unit 13 is in a range of 0.21 to 0.3. The area of the color gamut area surrounded by the first light-emitting unit 11, the second light-emitting unit 12 and the third light-emitting unit 13 is further limited through limiting the ranges of the chromaticity coordinates x and y of the first light-emitting unit 11, the second light-emitting unit 12 and the third light-emitting unit 13. Through this setting, within the same CCT range covered by the light-emitting device 10, the area of the color gamut area surrounded by the three light-emitting units is small, and the luminous efficiency of the light-emitting device 10 can be high.

It should be noted that in the light-emitting device 10 provided by the embodiment, each light-emitting unit can include a light-emitting chip and an encapsulant, and the encapsulant is covered on the light-emitting chip. The light-emitting chip can be a LED blue chip, the encapsulant can include phosphor, and transform a part of light emitted from the LED blue chip into light of another color with longer wavelength. Specifically, the first light-emitting unit 11 includes: a first light-emitting chip 111 and a first encapsulant 112, the second light-emitting unit 12 includes: a second light-emitting chip 121 and a second encapsulant 122, and the third light-emitting unit 13 includes: a third light-emitting chip 131 and a third encapsulant 132. In an embodiment, a dominant wavelength of the first light-emitting chip 111 is in a range of 445 nanometers (nm) to 460 nm, a full width at half maximum (FWHM) of the first light-emitting chip 111 is in a range of 16 nm to 20 nm, that is, the first light-emitting chip 111 can be a narrow-wavelength blue light chip. Dominant wavelengths of the second light-emitting chip 121 and the third light-emitting chip 131 are in a range of 445 nm to 460 nm, FWHMs of the second light-emitting chip 121 and the third light-emitting chip 131 are in a range of 16 nm to 20 nm, that is, the second light-emitting chip 121 and the third light-emitting chip 131 can be also narrow-wavelength blue light chips. In the embodiment, the first light-emitting chip 111, the second light-emitting chip 121 and the third light-emitting chip 131 can be exactly the same or different.

The first encapsulant 112, the second encapsulant 122 and the third encapsulant 132 are different from each other. Specifically, the first encapsulant 112, the second encapsulant 122 and the third encapsulant 132 can adopt same phosphor with different proportions of the phosphor, can also adopt different phosphor. In an embodiment, the first light-emitting unit 11 includes first red phosphor, the second light-emitting unit 12 includes second red phosphor, and the first red phosphor and the second red phosphor each can include nitride red phosphor (e.g., SCASN ((Sr, Ca)AlSiN₃:Eu²⁺), CASN (CaAlSiN₃), and BSSN (BaSi₂SN_{2.67})) and fluoride red phosphor (excepting for KSF (K₂SiF₆:Mn⁴⁺) phosphor, can be also fluorosilicate materials excited by 4-valent manganese such as KGF (K₂GeF₆:Mn⁴⁺) phosphor and KTF (K₂TiF₆:Mn⁴⁺) phosphor).

In an embodiment, as shown in FIG. 4, in the light-emitting device 10 provided by the embodiment, the first red phosphor and the second red phosphor are nitrides without fluoride. Through preparation of the phosphor, the peak wavelength of the light emitted from the first light-emitting unit 11 is in a range of 610 nm to 616 nm, the peak wavelength of the light emitted from the second light-emitting unit 12 is in a range of 582 nm to 588 nm, and the peak wavelength of the light emitted from the third light-emitting unit 13 is in a range of 440 nm to 460 nm. The disclosure can achieve a wide-range CCT tuning (e.g., 1800 K-10000 K), and make the CIExy coordinates (i.e., the CCT tuning trajectory) of the light-emitting device fit the blackbody radiation curve to tune the product during the tuning process.

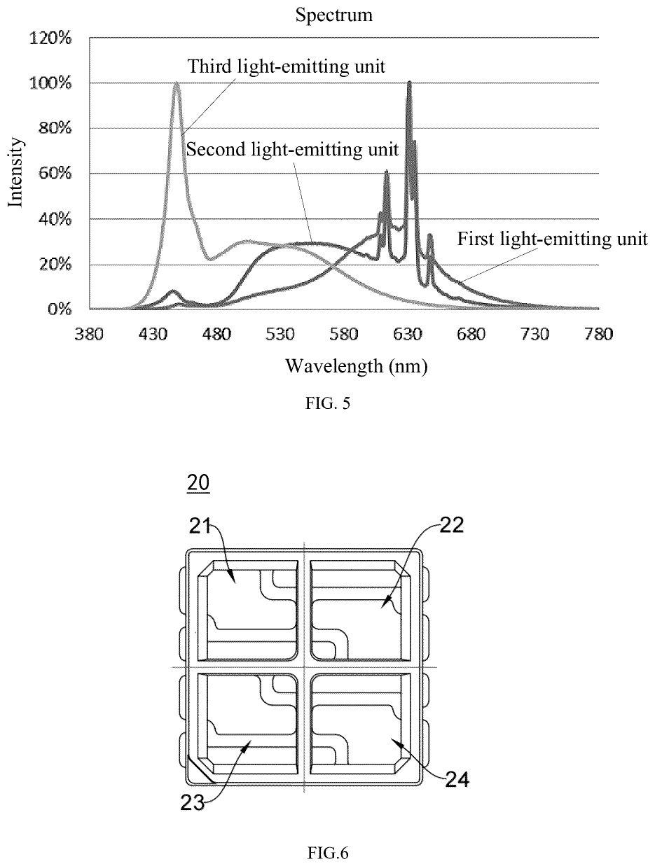

As shown in FIG. 5, in an embodiment, the first red phosphor and the second red phosphor can each include fluoride. In this situation, through the preparation of the phosphor, the peak wavelength of the light emitted from the first light-emitting unit is in a range of 630 nm to 634 nm, the peak wavelength of the light emitted from the second light-emitting unit is in a range of 630 nm to 634 nm, and the peak wavelength of the light emitted from the third light-emitting unit is in a range of 440 nm to 460 nm. The disclosure can achieve a wide-range CCT tuning (e.g., 1800 K-10000 K), and make the CIExy coordinates of the light-emitting device fit the blackbody radiation curve to tune the product during the tuning process.

For the light-emitting device 10 that the first red phosphor and the second red phosphor each include fluoride, a content of the fluoride in the first red phosphor can be greater than or equal to a content of the fluoride in the second red phosphor. In order to simplify the production process, optionally, the content of the fluoride in the first red phosphor is equal to the content of the fluoride in the second red phosphor. Since the fluoride phosphor has a high conversion efficiency, use of the fluoride phosphor can generally improve the luminous efficiency of the light-emitting device. However, there is a problem during using the fluoride phosphor currently, that is, color shift is serious. In order to reduce color shift, during processing the light-emitting unit using the fluoride phosphor, a layered dispensing technology is used, that is, when the encapsulant is covered on the chip, each phosphor is layered on the chip, a bottom layer (i.e., the phosphor closer to the chip) can be the fluoride, and an upper layer (i.e., the phosphor that is relatively farther away from the chip) can be a mixed colloid of yellow-green phosphor and the nitride red phosphor. In order to achieve a final light emission requirement and differentiation of the first light-emitting unit 11 and the second light-emitting unit 12, the first red phosphor and the second red phosphor each contain a certain amount of the nitride red phosphor, and a content of the nitride in the first red phosphor is greater than a content of the nitride in the second red phosphor. It should be noted that, whether the first light-emitting unit 11 and the second light-emitting unit 12 contain the fluorides or not, the encapsulant of the third light-emitting unit 13 does not contain red phosphor, and the content of the nitride in the first red phosphor is greater than the content of the nitride in the second red phosphor.

Table 1 shows a deviation situation of the chromaticity coordinates of the light-emitting device 10 of the disclosure at different use temperatures and different luminous CCTs. It can be seen from data in Table 1, the disclosure can effectively control the color shift of the light-emitting device, and absolute values of deviation amounts of Δx and Δy each do not exceed 0.01 at different use temperatures and different luminous CCTs, which can improve the compatibility of the product in different lamps.

TABLE 1

| | 2700 K | | 3000 K | | 4000 K | | 5000 K | | 6500 K | |
|---|---|---|---|---|---|---|---|---|---|---|
| Tc | Δx | Δy | Δx | Δy | Δx | Δy | Δx | Δy | Δx | Δy |
| 25° C. | 0 | 0 | 0 | 0 | 0 | 0 | 0 | 0 | 0 | 0 |
| 55° C. | 0.003 | −0.0030 | 0.0005 | −0.0031 | 0.0000 | −0.0037 | −0.0002 | −0.0039 | −0.0005 | −0.0046 |
| 85° C. | 0.007 | −0.0059 | 0.0007 | −0.0063 | −0.0001 | −0.0077 | −0.0006 | −0.0083 | −0.0011 | −0.0089 |

As described above, the light-emitting device 10 includes three different light-emitting units, which are driven independently. Through different current distribution for the three light-emitting units, the CCT of the final emitted light of the light-emitting device 10 can be in the range of 1800 K to 10000 K, and the chromaticity points all fall within the 4-step range of the corresponding CCT point on the blackbody radiation curve. That is, during the tuning process of the light-emitting device 10, the CIExy coordinates of the emitted light can fit the blackbody radiation curve, and a color tolerance can satisfy the requirements of 4-step.

In some embodiments, the light-emitting device 10 can also include a fourth light-emitting unit, and the fourth light-emitting unit has a same configuration with the first light-emitting unit 11, that is, the range of the dominant wavelength of the adopted chip and the composition of the used encapsulant of the fourth light-emitting unit are the same as that of the first light-emitting unit 11. In other words, the light-emitting device 10 includes two first light-emitting units 11 and 11′, and the settings of the two first light-emitting units 11/11′ can achieve that the maximum current used by each light-emitting unit during the adjustment process is as close as possible, and the power of the light-emitting device 10 can be greater.

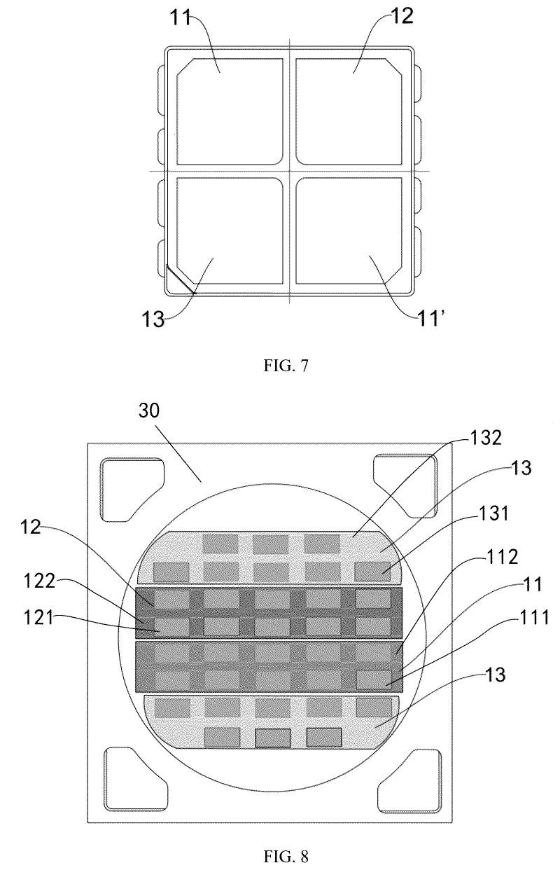

Specifically, as shown in FIG. 6 and FIG. 7, a specific structure of the light-emitting device 10 provided by the embodiment of the disclosure includes a bracket 20, and the bracket 20 defines a first accommodating slot 21, a second accommodating slot 22, a third accommodating slot 23 and a fourth accommodating slot 24 that can be independently driven. The light-emitting device 10 includes four light-emitting units, specifically including a first light-emitting unit 11, a second light-emitting unit 12, a third light-emitting 13 and another first light-emitting unit 11′. The two first light-emitting units 11/11′ can be disposed in the first accommodating slot 21 and the fourth accommodating slot 24, the second light-emitting unit 12 is disposed in the second accommodating slot 22, and the third light-emitting unit 13 is disposed in the third accommodating slot 23. Specifically, the first accommodating slot 21 and the fourth accommodating slot 24 are distributed diagonally, which can make the light mixing effect better.

In an embodiment, during adjusting the CCT from 1800 K to 10000 K by tuning the four light-emitting units along the blackbody radiation curve, current ratios of the first light-emitting units 11/11′ decrease and then increase with the increase of the CCT, a current ratio of the second light-emitting unit 12 increases and then decreases with the increase of the CCT, and a current ratio of the third light-emitting unit 13 increases with the increase of the CCT. As shown in Table 2, the light-emitting device 10 including two first light-emitting units 11/11′, a second light-emitting unit 12 and a third light-emitting unit 13 provided by the embodiment is taken as an example. A sum of the current ratios of the two first light-emitting units 11/11′, the second light-emitting unit 12 and the third light-emitting unit 13 is 100%, and the current ratios of the two first light-emitting units 11/11′ can be the same. When the CCT is 1800 K, the current ratios of the first light-emitting units 11/11′ are 50%; when the CCT is 2200 K, the current ratios of the first light-emitting units 11/11′ are 35%; when the CCT is 4000 K, the current ratios of the first light-emitting units 11/11′ are 13.5%; when the CCT is 6500 K, the current ratios of the first light-emitting units 11/11′ are 8.6%; that is, the current ratios of the first light-emitting units 11/11′ decrease with the increase of the CCT when the CCT ranges from 1800 K to 6500 K. When the CCT is 8000 K, the current ratios of the first light-emitting units 11/11′ are 9.0%; when the CCT is 10000 K, the current ratios of the first light-emitting units 11/11′ are 10.2%; that is, the current ratios of the first light-emitting units 11/11′ increase with the increase of the CCT when the CCT ranges from 6500 K to 10000 K; that is, the current ratios of the first light-emitting units 11/11′ decrease and then increase with the increase of the CCT. When the CCT is 1800 K, the current ratio of the second light-emitting unit 12 is 0%; when the CCT is 3000 K, the current ratio of the second light-emitting unit 12 is 46.6%; when the CCT is 4000 K, the current ratio of the second light-emitting unit 12 is 49.8%; that is, the current ratio of the second light-emitting unit 12 increases with the increase of the CCT when the CCT ranges from 1800 K to 4000 K. When the CCT is 5000 K, the current ratio of the second light-emitting unit 12 is 43.2%; when the CCT is 6500 K, the current ratio of the second light-emitting unit 12 is 30.8%; when the CCT is 8000 K, the current ratio of the second light-emitting unit 12 is 19.9%; when the CCT is 10000 K, the current ratio of the second light-emitting unit 12 is 9%; that is, the current ratio of the second light-emitting unit 12 decreases with the increase of the CCT when the CCT ranges from 4000 K to 10000 K; that is, the current ratio of the second light-emitting unit 12 increases and then decreases with the increase of the CCT. When the CCT is 1800 K, the current ratio of the third light-emitting unit 13 is 0%; when the CCT is 3000 K, the current ratio of the third light-emitting unit 13 is 10.5%; when the CCT is 6500 K, the current ratio of the third light-emitting unit 13 is 51.9%; when the CCT is 8000 K, the current ratio of the third light-emitting unit 13 is 62%; when the CCT is 10000 K, the current ratio of the third light-emitting unit 13 is 70.7%; that is, the current ratio of the third light-emitting unit 13 increases with the increase of the CCT.

TABLE 2

| | Current ratio | | | |
|---|---|---|---|---|
| | First light- | First light- | Second light- | Third light- |
| | emitting | emitting | emitting | emitting |
| CCT | unit 11 | unit 11′ | unit 12 | unit 13 |
| 1800K | 50.0% | 50.0% | 0.0% | 0.0% |
| 2200K | 35.0% | 35.0% | 29.7% | 0.4% |
| 2700K | 25.8% | 25.8% | 42.5% | 6.0% |
| 3000K | 21.4% | 21.4% | 46.6% | 10.5% |
| 3500K | 17.3% | 17.3% | 49.2% | 16.2% |
| 4000K | 13.5% | 13.5% | 49.8% | 23.2% |
| 5000K | 10.2% | 10.2% | 43.2% | 36.5% |
| 5700K | 9.6% | 9.6% | 36.8% | 44.0% |
| 6500K | 8.6% | 8.6% | 30.8% | 51.9% |
| 8000K | 9.0% | 9.0% | 19.9% | 62.0% |
| 10000K | 10.2% | 10.2% | 9.0% | 70.7% |

As shown in Table 3, based on the consideration of the maximum power that can be used by the first light-emitting unit 11, the second light-emitting unit 12, and the third light-emitting unit 13, an embodiment of the chromaticity points of the first light-emitting unit 11, the second light-emitting unit 12, and the third light-emitting unit 13 can be as shown in Table 3, and the current ratios of the first light-emitting unit 11, the second light-emitting unit 12, and the third light-emitting unit 13 with the mixed white light CCT ranging from 1800 K to 6500 K are as shown in Table 2. The coordinates of the chromaticity points of the first light-emitting unit 11, the second light-emitting unit 12, and the third light-emitting unit 13 in Table 3 are taken as examples, when the CCT is 1800 K, the current ratio of the first light-emitting unit 11 is close to 50%, when the CCT is 3500 K or 4000 K, the current ratio of the second light-emitting unit 12 is close to 50%, and when the CCT is 6500 K, the current ratio of the third light-emitting unit 13 is close to 50%, which can maximize the wattage of the CCT tuned by the light-emitting device 10. When the chromaticity coordinate x of the first light-emitting unit 11 increases, the tuning along the blackbody radiation curve can be also achieved, but in each target CCT, the current ratio of the first light-emitting unit 11 will decrease, and the current ratio of the second light-emitting unit 12 will increase. Meanwhile, when the chromaticity coordinate x of the first light-emitting unit 11 increases, the brightness will decrease, and when the chromaticity coordinate x is greater than 0.53, the larger the chromaticity coordinate x, the lower the brightness. When the chromaticity coordinate x of the first light-emitting unit 11 decreases to be smaller than 0.53, the tuning with the CCT of 1800 K cannot be achieved at the same time. When the chromaticity coordinate x of the second light-emitting unit 12 increases, in each target CCT, the current ratio of the second light-emitting unit 12 will decrease, and the current ratio of the first light-emitting unit 11 will increase. When the chromaticity coordinate x of the second light-emitting unit 12 ranges from 0.4 to 0.48, the larger the chromaticity coordinate x, the lower the brightness. When the chromaticity coordinate x of the third light-emitting unit 13 increases, the current ratio of the third light-emitting unit 13 will increase, and when the chromaticity coordinate x of the third light-emitting unit 13 decreases, the current ratio of the third light-emitting unit 13 will decrease. When the chromaticity coordinate x of the third light-emitting unit 13 is smaller than 0.24, the larger the chromaticity coordinate x, the higher the brightness.

TABLE 3

| | | | CCT | Peak wavelength |
|---|---|---|---|---|
| | x | y | (K) | (Wp) (nm) |
| First light-emitting unit | 0.5471 | 0.3973 | 1753 | 631 |
| Second light-emitting unit | 0.4162 | 0.4675 | 3800 | 631 |
| Third light-emitting unit | 0.2176 | 0.2626 | 0 | 448 |

A specific structure of the light-emitting device 10 provided by the embodiment of the disclosure is shown in FIG. 2, the first light-emitting unit 11 can include a first light-emitting chip 111 and a first encapsulant 112 covering the first light-emitting chip 111, the second light-emitting unit 12 can include a second light-emitting chip 121 and a second encapsulant 122 covering the second light-emitting chip 121, and the third light-emitting unit 13 can include a third light-emitting chip 131 and a third encapsulant 132 covering the third light-emitting chip 131.

A specific structure of the light-emitting device 10 provided by the embodiment of the disclosure can be also shown in FIG. 8. A chip on board (COB) substrate 30 is provided with multiple first light-emitting chips 111, multiple second light-emitting chips 121 and multiple third light-emitting chips 131 thereon. The first encapsulant 112 covers the multiple first light-emitting chips 111 to form the first light-emitting unit 11, the second encapsulant 122 covers the multiple second light-emitting chips 121 to form the second light-emitting unit 12, and the third encapsulant 132 covers the multiple third light-emitting chips 131 to form the third light-emitting unit 13.

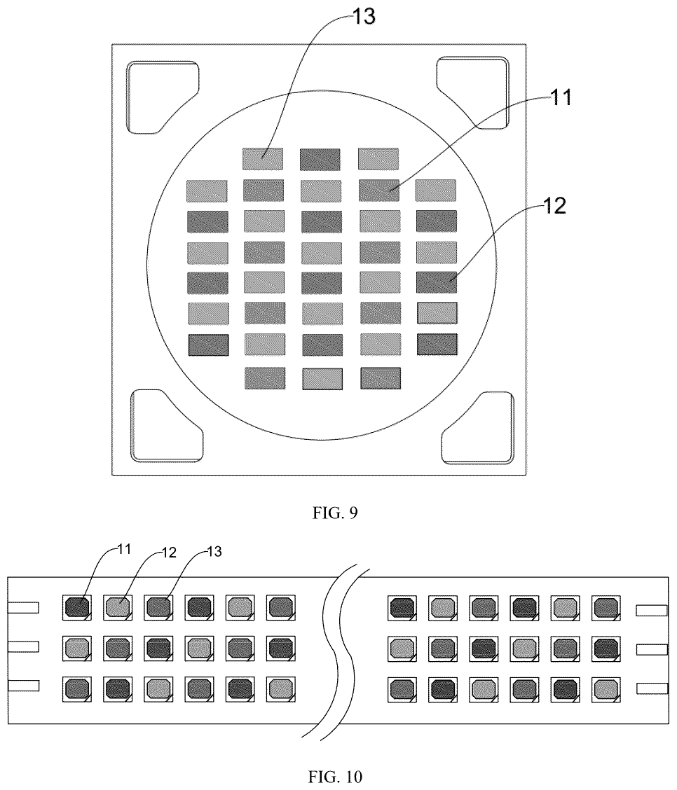

Another specific structure of the light-emitting device 10 provided by the embodiment of the disclosure can be also shown in FIG. 9. A substrate is provided with multiple first light-emitting units 11, multiple second light-emitting units 12 and multiple third light-emitting units 13 in chip-scale packaging (CSP). The first light-emitting units 11, the second light-emitting units 12 and the third light-emitting units 13 are arranged in a checkerboard staggered way.

Still another specific structure of the light-emitting device 10 provided by the embodiment of the disclosure can be also shown in FIG. 10. The multiple first light-emitting units 11, the multiple second light-emitting units 12 and the multiple third light-emitting units 13 can be surface mounted devices (SMD) such as surface mounted light lamps. The first light-emitting units 11, the second light-emitting units 12 and the third light-emitting units 13 are arranged alternately on a substrate to form a light emitting device 10 in a form of a light board or light strip. Of course, the above is merely an example and this embodiment is not limited to it.

In summary, the embodiment of the disclosure sets the light emitting device 10 to include at least three different light-emitting units, and through the specific selection of the chromaticity point, the peak wavelength and the FWHM of each light-emitting unit, the area surrounded by the chromaticity points of the first light-emitting unit 11, the second light-emitting unit 12 and the third light-emitting unit 13 covers the area with the CCT range of 1800 K to 10000 K on the black body radiation curve. As shown in FIG. 3, the light-emitting device 10 provided in the embodiment can achieve a wide-range of CCT tuning (such as 1800 K-10000 K), thereby ensuring that the target CCT range falls within the range of 4 steps on the blackbody radiation curve within this CCT range.

In addition, it can be understood that the aforementioned embodiments are merely exemplary descriptions of the disclosure. Under the premise that the technical features do not conflict, the structures do not contradict, and the purpose of the disclosure is not violated, the technical solutions of the various embodiments can be arbitrarily combined and used in combination.

Finally, it should be noted that the above embodiments are merely used to illustrate the technical solutions of the disclosure, rather than to limit then. Although the disclosure has been described in detail with reference to the aforementioned embodiments, those skilled in the art should understand that they can still modify the technical solutions described in the aforementioned embodiments, or make equivalent replacements for some of the technical features therein. However, these modifications or replacements do not deviate the essence of the corresponding technical solutions from the spirit and scope of the technical solutions of the embodiments of the disclosure.

What is claimed is:

1. A light-emitting device, comprising:
a first light-emitting unit, wherein a chromaticity coordinate x of the first light-emitting unit is in a range of 0.53 to 0.6, and a chromaticity point of the first light-emitting unit is located proximate to a blackbody radiation curve;
a second light-emitting unit, wherein a chromaticity coordinate x of the second light-emitting unit is in a range of 0.4 to 0.48, and a chromaticity point of the second light-emitting unit is located above the blackbody radiation curve; and
a third light-emitting unit, wherein a chromaticity coordinate x of the third light-emitting unit is in a range of 0.18 to 0.24, and a chromaticity point of the third light-emitting unit is located above the blackbody radiation curve; and
wherein an area surrounded by the chromaticity point of the first light-emitting unit, the chromaticity point of the second light-emitting unit and the chromaticity point of the third light-emitting unit covers an area on the blackbody radiation curve with a correlated color temperature range of 1800 Kelvin (K) to 10000 K.

2. The light-emitting device as claimed in claim 1, wherein a distance between the chromaticity point of the first light-emitting unit and the chromaticity point of the second light-emitting unit is in a range of 0.12 to 0.16, a distance between the chromaticity point of the second light-emitting unit and the chromaticity point of the third light-emitting unit is in a range of 0.27 to 0.34, and a distance between the chromaticity point of the third light-emitting unit and the chromaticity point of the first light-emitting unit is in a range of 0.32 to 0.38.

3. The light-emitting device as claimed in claim 1, wherein a chromaticity coordinate y of the first light-emitting unit is in a range of 0.4 to 0.43, a chromaticity coordinate y of the second light-emitting unit is in a range of 0.45 to 0.56, and a chromaticity coordinate y of the third light-emitting unit is in a range of 0.21-0.3.

4. The light-emitting device as claimed in claim 1, wherein the first light-emitting unit comprises: a first light-emitting chip and a first encapsulant, the second light-emitting unit comprises: a second light-emitting chip and a second encapsulant, and the third light-emitting unit comprises: a third light-emitting chip and a third encapsulant; and the first encapsulant comprises first red phosphor, and the second encapsulant comprises second red phosphor.

5. The light-emitting device as claimed in claim 4, wherein a dominant wavelength of each of the first light-emitting chip, the second light-emitting chip and the third light-emitting chip is in a range of 445 nm to 460 nm, and a full width at half maximum (FWHM) of each of the first light-emitting chip, the second light-emitting chip and the third light-emitting chip is in a range of 16 nm to 20 nm.

6. The light-emitting device as claimed in claim 4, wherein the first red phosphor and the second red phosphor each comprise nitrides, a peak wavelength of light emitted from the first light-emitting unit is in a range of 610 nm to 616 nm, a peak wavelength of light emitted from the second light-emitting unit is in a range of 582 nm to 588 nm, and a peak wavelength of light emitted from the third light-emitting unit is in a range of 440 nm to 460 nm.

7. The light-emitting device as claimed in claim 4, wherein the first red phosphor and the second red phosphor each comprise fluoride, a peak wavelength of light emitted from the first light-emitting unit is in a range of 630 nm to 634 nm, a peak wavelength of light emitted from the second light-emitting unit is in a range of 630 nm to 634 nm, and a peak wavelength of light emitted from the third light-emitting unit is in a range of 440 nm to 460 nm.

8. The light-emitting device as claimed in claim 6, wherein a content of the nitride in the first red phosphor is greater than a content of the nitride in the second red phosphor.

9. The light-emitting device as claimed in claim 7, wherein a content of the fluoride in the first red phosphor is greater than or equal to a content of the fluoride in the second red phosphor.

10. The light-emitting device as claimed in claim 2, further comprising: a fourth light-emitting unit, wherein the fourth light-emitting unit is the same as the first light-emitting unit.

11. The light-emitting device as claimed in claim 10, further comprising:
a bracket, wherein the bracket defines a first accommodating slot, a second accommodating slot, a third accommodating slot and a fourth accommodating slot, the first light-emitting unit is disposed in the first accommodating slot, the second light-emitting unit is disposed in the second accommodating slot, the third light-emitting unit is disposed in the third accommodating slot, and the fourth light-emitting unit is disposed in the fourth accommodating slot.

12. The light-emitting device as claimed in claim 11, wherein the first accommodating slot and the fourth accommodating slot are distributed diagonally.

13. The light-emitting device as claimed in claim 1, wherein the first light-emitting unit, the second light-emitting unit and the third light-emitting unit are chip-scale packaged.

14. The light-emitting device as claimed in claim 1, wherein a number of the first light-emitting unit, the second light-emitting unit and the third light-emitting unit is multiple, and the multiple first light-emitting units, the multiple second light-emitting units and the multiple third light-emitting units are arranged in a checkerboard staggered way.

15. The light-emitting device as claimed in claim 1, wherein the first light-emitting unit comprises: multiple first light-emitting chips and a first encapsulant covering the multiple first light-emitting chips; the second light-emitting unit comprises: multiple second light-emitting chips and a second encapsulant covering the multiple second light-emitting chips; the third light-emitting unit comprises: multiple third light-emitting chips and a third encapsulant covering the multiple third light-emitting chips; and the first light-emitting unit, the second light-emitting unit and the third light-emitting unit are disposed on a chip on board (COB) substrate.

16. The light-emitting device as claimed in claim 1, wherein a number of the first light-emitting unit, the second light-emitting unit and the third light-emitting unit is multiple, and the multiple first light-emitting unit, the multiple second light-emitting unit and the multiple third light-emitting unit are surface mounted devices (SMD), and are arranged alternately on a substrate.

17. A light-emitting device, comprising:
a first light-emitting unit, wherein a peak wavelength of light emitted from the first light- emitting unit is in a range of 610 nm to 616 nm;
a second light-emitting unit, wherein a peak wavelength of light emitted from the second light-emitting unit is in a range of 582 nm to 588 nm; and
a third light-emitting unit, wherein a peak wavelength of light emitted from the third light-emitting unit is in a range of 440 nm to 460 nm.

18. The light-emitting unit as claimed in claim 17, wherein the first light-emitting unit comprises: a first light-emitting chip and a first encapsulant, the second light-emitting unit comprises: a second light-emitting chip and a second encapsulant, and the third light-emitting unit comprises: a third light-emitting chip and a third encapsulant; and the first encapsulant comprises first red phosphor, and the second encapsulant comprises second red phosphor, and the first red phosphor and the second red phosphor each comprise nitrides.

19. A light-emitting device, comprising:
a first light-emitting unit, wherein a peak wavelength of light emitted from the first light-emitting unit is in a range of 630 nm to 634 nm;
a second light-emitting unit, wherein a peak wavelength of light emitted from the second light-emitting unit is in a range of 630 nm to 634 nm; and
a third light-emitting unit, wherein a peak wavelength of light emitted from the third light-emitting unit is in a range of 440 nm to 460 nm.

20. The light-emitting unit as claimed in claim 19, wherein the first light-emitting unit comprises: a first light-emitting chip and a first encapsulant, the second light-emitting unit comprises: a second light-emitting chip and a second encapsulant, and the third light-emitting unit comprises: a third light-emitting chip and a third encapsulant; and the first encapsulant comprises first red phosphor, and the second encapsulant comprises second red phosphor, and the first red phosphor and the second red phosphor each comprise fluoride.
